(19) United States
(12) Patent Application Publication
(10) Pub. No.: US 2024/0384407 A1
(43) Pub. Date: Nov. 21, 2024

(54) METHOD FOR SYNTHESIZING 2H/1T' TMD HETEROPHASE JUNCTIONS AND A DEVICE BASED ON THE SAME

(71) Applicant: City University of Hong Kong, Hong Kong (HK)

(72) Inventors: Hua ZHANG, Hong Kong (HK); Yongji WANG, Hong Kong (HK); Wei ZHAI, Hong Kong (HK)

(21) Appl. No.: 18/320,991

(22) Filed: May 21, 2023

(51) Int. Cl. C23C 16/455; C23C 16/52

(52) U.S. Cl. CPC C23C 16/45523; C23C 16/52

(57) ABSTRACT

Provided is a method for synthesizing 2H/1T′ transition metal dichalcogenide (TMD) heterophase junctions. Synthesis of vertical 2H/1T′ MoS₂ heterophase junction is achieved by growing 2H MoS₂ monolayers on a mica substrate under pure Ar carrier gas, and then growing 1T′ MoS₂ nanoribbons on top of the 2H MoS₂ monolayers by changing the carrier gas from pure Ar to a mixture of Ar and H₂ gases. The integrated devices based on 2H/1T′ MoS₂ heterophase structures display typical rectifying behavior with a current rectifying ratio of over 10₂ and achieve a responsivity of 1.07 A/W at 532 nm with an ultra-low dark current of lower than 10⁻¹¹ A. These superior features make 2H/1T′ MoS₂ heterophase structure a promising candidate for future rectifiers as well as photodetectors. More importantly, the provided synthesis method can pave the way toward tailoring the phase in MoS₂ to promote the performance of electronic devices.

### FIELD OF THE INVENTION

The present invention generally relates to transition metal dichalcogenide (TMD) heterophase junctions. More specifically, the present invention relates to a chemical vapour deposition (CVD) method for growing 2H/1T′ MoS₂ heterophase junctions.

### BACKGROUND OF THE INVENTION

Two-dimensional (2D) TMDs have attracted much interest due to their diverse properties ranging from insulators, semiconductors, semi-metals, to true metals. When different 2D materials are stacked vertically, the advantages of multiple materials can be combined. With the development of phase engineering of nanomaterials (PEN), crystal phase of TMDs has become one of the most important structural features beyond size, morphology, and symmetry, which determines the intrinsic properties of TMDs. Unlike thermodynamically stable phases, plenty of unconventional phases exhibit distinct properties.

For example, 2H MoS₂ typically shows a semiconducting feature, while IT and 1T′ MoS₂ normally display the metallic characteristic. Heterojunctions, especially heterophase junctions, have gained more attention since they can act as high-performance devices such as rectifiers, detectors and transistors for energy storage, electrocatalysis as well as optoelectronics. Many works have indicated that the coexistence of semiconducting and metallic polymorphs in 2D heterophase junctions is extremely significant to improve carrier mobility, thereby improving the overall performance of the device.

1T′ MoS₂ has a semi-metallic phase with high electrical conductivity and shows a lower contact barrier with 2H MoS₂ compared to metal-contacted 2H MoS₂. Herein, by precise controlling of synthesis conditions, the in situ growth of 2H/1T′ MoS₂ heterophase junctions was realized. The prepared junctions show clean van der Walls interfaces, which facilitates the fast photo response time and high photoresponsivity.

However, existing methods for obtaining MoS₂ heterophase junctions are usually based on manual stacking and local phase transformation, which will inevitably introduce contaminants and interface defects. Moreover, existing approaches of mass production for MoS₂ heterophase junctions strongly rely on post-treatments, such as laser irradiation, lithium intercalation, chemical doping which reaction conditions are complex and harsh, and controllability is poor. Direct epitaxial (or in-situ) growth of metastable 1T′ MoS₂ on 2H MoS₂ heterophase junction with high purity and a clear van der Waals interface is still quite challenging because the formation energy of 1T′ phase is much higher than that of the 2H phase.

### SUMMARY OF THE INVENTION

In accordance with a first aspect of the present disclosure, a CVD method for growing 2H/1T′ TMD heterophase junction is provided. The method comprises: mixing a transition metal compound powder and a first chalcogen powder to form a first mixture; heating up the first mixture to a first heating temperature in a chemical vapour deposition (CVD) furnace filled with Ar gas; keeping the first mixture at the first heating temperature for a first heating time under a first mixed gas flow of H₂ and Ar to form a first precursor; mixing the first precursor with a second chalcogen powder to form a second mixture; heating up the second mixture to a second heating temperature in a CVD furnace filled with Ar gas; keeping the second mixture at the second heating temperature for a second heating time under a second mixed gas flow of H₂ and Ar to form a second precursor; placing a substrate on top of the second precursor; heating up the second precursor and the substrate to a growth temperature in a CVD furnace filled with Ar gas; keeping the second precursor and the substrate at the growth temperature for a first growth time under a gas flow of Ar to grow a 2H TMD layer on the substrate; keeping the second precursor and the substrate at the growth temperature for a second growth time under a third mixed gas flow of H₂ and Ar to grow a 1T′ TMD layer above the grown 2H TMD layer on the substrate; and cooling down rapidly the substrate grown with the 2H/1T′ TMD heterophase junctions.

In a further aspect, the method further comprises grinding the first mixture in an agate mortar, transferring the first mixture into a first alumina crucible and placing the first alumina crucible at a center position in the CVD furnace before heating up the first mixture in the CVD furnace.

In a further aspect, the method further comprises transferring the second mixture into a second alumina crucible and placing the second alumina crucible at a center position in the CVD furnace before heating up the second mixture in the CVD furnace.

In a further aspect, the method further comprises transferring the second precursor into a quartz crucible before the substrate being placed on top of the second precursor and placing the quartz crucible at a center position in the CVD furnace before heating up the third mixture in the CVD furnace.

In a further aspect, the substrate is a fluorophlogopite mica substrate or a sapphire substrate.

In a further aspect, a flow rate ratio for H₂ to Ar in the first mixed gas flow is equal to 1:9; and the first temperature ranges from 400 to 500° C. and the first heating time ranges from 1 to 2 hours,

In a further aspect, a flow rate ratio for H₂ to Ar in the second mixed gas flow is equal to 1:9; and the second temperature ranges from 400 to 500° C. and the second heating time ranges from 1 to 2 hours.

In a further aspect, a flow rate ratio for H₂ to Ar in the third mixed gas flow is equal to 2:8; and the third temperature ranges from 750 to 800° C. and the third heating time ranges from 4 to 6 minutes.

In a further aspect, the transition metal compound powder is a molybdenum compound powder and both the first and second chalcogen powders are sulfur powders such that the 2H/1T′ TMD heterophase junctions grown on the substrate are 2H/1T′ molybdenum disulfide heterophase junctions.

In a further aspect, the molybdenum compound powder is a potassium molybdate (K₂MoO₄) powder.

In accordance with a second aspect of the present disclosure, 2H/1T′ TMD heterophase junction-based device is provided. The 2H/1T′ TMD heterophase junction-based device comprises: a substrate; a 2H/1T′ TMD heterophase junction deposited on the substrate and including a 1T′-TMD region and a 2H-TMD region; and a pair of electrodes connected to the 1T′-TMD and the 2H-TMD regions respectively.

In a further aspect, the 1T′-TMD region is formed of 1T′-MoS₂ crystal and the 2H-TMD region is formed of 2H-MoS₂ crystal.

In a further aspect, the substrate is a SiO₂/Si substrate.

In a further aspect, the electrodes are made of Cr/Au layer.

It is gratifying that in the synthesized 2H/1T′ MoS₂ heterophase junction, the grown 1T′ MoS₂ nanoribbon can extend over the region of 2H MoS₂ monolayer, which allows direct fabrication of devices utilizing the as-prepared heterophase junctions without any additional post-treatment process. Therefore, the present invention offers a new strategy in the field of phase engineering, which could also be used for preparation of other heterophase junctions.

In accordance with a second aspect of the present disclosure, a device based on 2H/1T′ TMD heterophase junction may be fabricated using the CVD method provided by the present invention. For example, the fabricated 2H/1T′ MoS₂ heterophase junction-based device displays outstanding behaviors of rectification and exhibits high responsivity and fast raise time, indicating the great potential of 2H/1T′ MoS₂ heterophase junction in future optoelectronics application. In addition, the 2H/1T′ MoS₂ heterophase junction can serve as an anisotropic conductor and micro-cell catalyst.

### BRIEF DESCRIPTION OF THE DRAWINGS

Embodiments of the invention are described in more details hereinafter with reference to the drawings, in which:

FIGS. 1A to 1C shows three main stages of a general method for growing 2H/1T′ TMD heterophase junctions according to some embodiments of the present invention;

FIG. 2A shows a schematic diagram and a typical optical image (insert of FIG. 2A) of the prepared 2H/1T′ MoS₂ heterophase junctions; FIGS. 2B and 2C show other optical images of the synthesized 2H/1T′ MoS₂ heterophase junctions in different scales;

FIGS. 3A and 3B show transmission electron microscope (TEM) images of the prepared 2H/1T′ MoS₂ heterophase junctions;

FIG. 4 shows a schematic diagram of the prepared 2H/1T′ MoS₂ heterophase junctions;

FIG. 5 shows the aberration-corrected high-angle annular dark-field (HAADF) scanning transmission electron microscopy (STEM) cross-section image of the prepared 2H/1T′ MoS₂ heterophase junctions;

FIGS. 6A and 6B show high-resolution (HR) TEM images of the 2H MoS₂ and 1T′ MoS₂ regions respectively;

FIGS. 7A and 7B show atomically resolved HAADF-STEM images of the 2H MoS₂ and 1T′ MoS₂ respectively; insets of FIGS. 7A and 7B show selected area electron diffraction (SAED) pattern of the 2H MoS₂ and 1T′ MoS₂ regions respectively;

FIG. 8 shows a dark-field HRTEM image of the 2H/1T′ MoS₂ heterophase junctions;

FIGS. 9A to 9C show elemental mapping images of Mo L signals, S K signals and overlap of Mo L and S K signals for the 2H/1T′ MoS₂ heterophase junctions, respectively;

FIG. 10 shows Raman spectra of 2H MoS₂ layer, 1T′ MoS₂ layer, and mica substrate;

FIGS. 11A and 11B show the angle-dependent Raman intensities of 2H MoS₂ and 1T′ MoS₂ regions respectively;

FIG. 12 shows photoluminescence (PL) spectra of 2H MoS₂ and 1T′ MoS₂ regions respectively;

FIGS. 13A and 13B show thickness measurement results of 2H MoS₂ and 1T′ MoS₂ regions respectively;

FIG. 14 shows the atomic force microscope (AFM) image of the 2H/1T′ MoS₂ heterophase junctions;

FIGS. 15A and 15B show micro-zone X-ray photoelectron spectroscopy (XPS) spectra of the Mo 3d and S 2p orbits of the 2H MoS₂ and 1T′ MoS₂ regions among the 2H/1T′ MoS₂ heterophase junctions respectively;

FIGS. 16A and 16B show XPS spectra of the K 2p orbits of the 2H MoS₂ and 1T′ MoS₂ regions respectively;

FIGS. 17A and 17B show Raman mapping images of the 2H MoS₂ and 1T′ MoS₂ regions respectively;

FIG. 18 shows schematic diagram of a heterophase junction device based on 2H/1T′ TMD heterophase junctions according to some embodiments of the present invention;

FIG. 19 shows a typical optical image of the 2H/1T′ MoS₂ heterophase junction device respectively;

FIG. 20 shows the corresponding AFM image of the 2H/1T′ MoS₂ heterophase junction device;

FIG. 21A shows the transfer curve and FIG. 21B shows I_{ds}-V_{ds} characteristic curves under different gate voltages of the 2H/1T′ MoS₂ heterophase junction device;

FIG. 22A shows the transfer curve and FIG. 22B shows I_{ds}-V_{ds} characteristic curves under different gate voltages of a comparative 2H MoS₂ device;

FIG. 23A shows curves of time-resolved photocurrents of the 2H/1T′ MoS₂ heterophase junction device at different V_{ds} biases under a 532 nm laser with 3.52 mW/cm² input power; FIG. 23B show a close-up view of the curves of FIG. 23A;

FIG. 24 show photo-switching characteristics of the 2H/1T′ MoS₂ heterophase junction device for different wavelengths.

### DETAILED DESCRIPTION

In the following description, embodiments of the present invention are set forth as preferred examples. It will be apparent to those skilled in the art that modifications, including additions and/or substitutions may be made without departing from the scope and spirit of the invention. Specific details may be omitted so as not to obscure the invention, however, the disclosure is written to enable one skilled in the art to practice the teachings herein without undue experimentation.

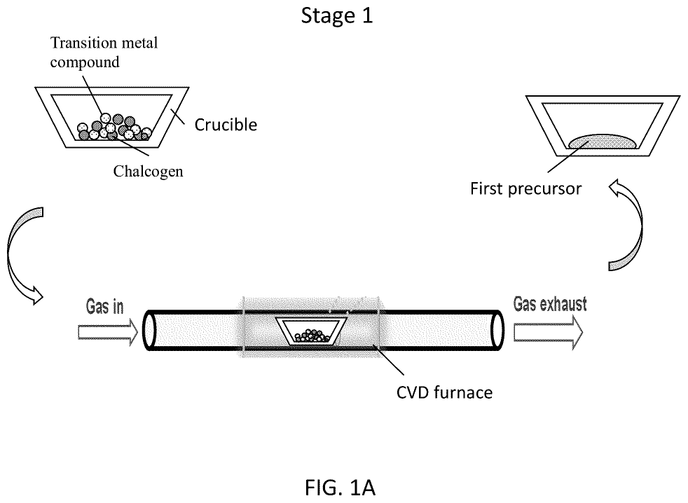

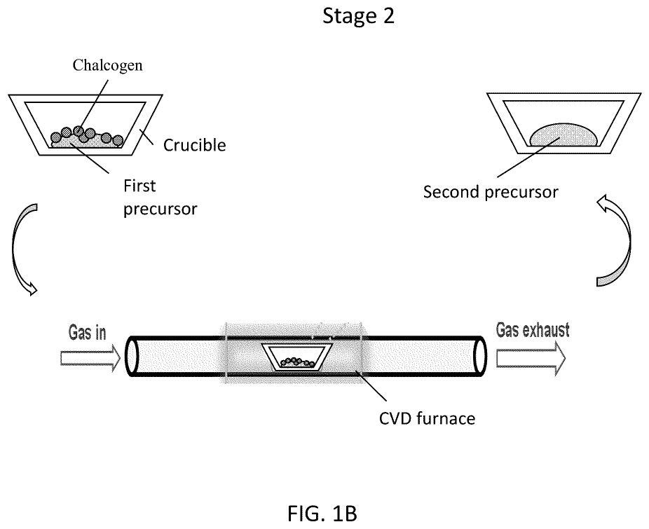

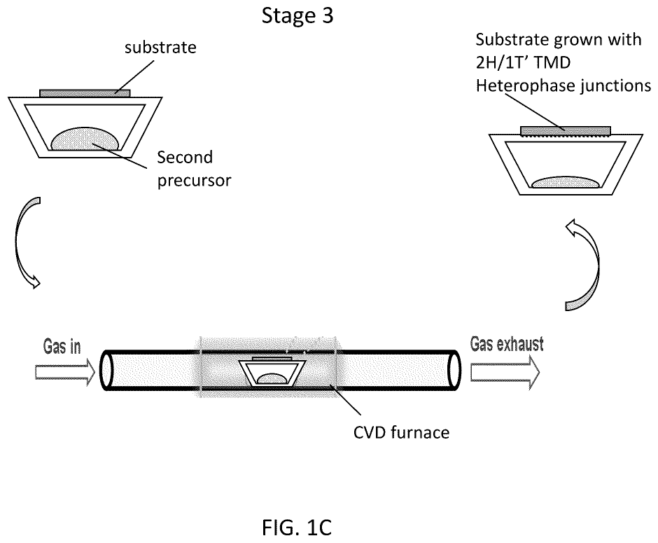

In accordance with one aspect of the present invention, a general method for growing 2H/1T′ TMD heterophase junctions is provided. The method adopts a one-pot synthesis strategy and comprises three main stages as shown in FIGS. 1A to 1C respectively.

Referring to FIG. 1A, in Stage 1, a transition metal compound powder and a first chalcogen powder are mixed to form a first mixture. The first mixture is ground in an agate mortar and then transferred into a first alumina crucible. The first alumina crucible is then placed at a center position in the CVD furnace. After filling the CVD furnace with argon (Ar) gas, the first mixture is heated up to a first heating temperature and then kept at the first heating temperature for a first heating time under a first mixed gas flow of H₂ and Ar to form a first precursor. The first precursor is then cooled down to room temperature naturally.

Referring to FIG. 1B, in Stage 2, the first precursor is mixed with a second chalcogen powder to form a second mixture. The second mixture is transferred to a second alumina crucible. The second alumina crucible is then placed at a center position in a CVD furnace. After filling the CVD furnace with Ar gas, the second mixture heated up to a second heating temperature, and then kept at the second heating temperature for a second heating time under a second mixed gas flow of H₂ and Ar to form a second precursor. The second precursor is then cooled down to room temperature naturally.

Referring to FIG. 1C, in Stage 3, after the second precursor is loaded into a quartz crucible, one piece of substrate is placed on top of the second precursor. The quartz crucible and the substrate is then placed at a center position in a CVD furnace. After filling the CVD furnace with Ar gas, the second precursor and the substrate is heated up to a first growth temperature, and kept at the first growth temperature for a first growth time under a gas flow of Ar to grow a 2H TMD crystal layer.

Then the second precursor and the substrate are kept at a second growth temperature for a second growth time under a mixed gas flow of H₂ and Ar to grow a 1T′ TMD layer on the grown 2H TMD layer such that 2H/1T′ TMD heterophase junctions are formed. Then the substrate grown with the 2H/IT′ TMD heterophase junctions are taken out of the CVD furnace and cooled down rapidly.

### Synthesis of 2H/1T′ MoS₂ Heterophase Junctions

The synthesis of vertical 2H/1T′ MoS₂ heterophase junction is achieved by simply changing the carrier gas. Briefly, 2H MoS₂ monolayers are first grown on a mica substrate under an atmosphere of pure Ar gas. Then, 1T′ MoS₂ nanoribbons are continuously grown on the top of 2H MoS₂ monolayers by changing the carrier gas from pure Ar to a mixture of Ar and hydrogen (H₂) gases. leading to the formation of 2H/1T′ heterophase junction.

In a typical synthesis, potassium molybdate (K₂MoO₄) (600 mg) and sulfur powder (600 mg) were mixed in an agate mortar and then ground for 10 mins. Then the obtained homogeneous mixture was transferred into an alumina crucible and the alumina crucible was placed in the center of the furnace. Subsequently, the quartz tube was vacuumed and refilled with Ar for three times. After purging the tube with Ar (500 s.c.c.m) for 10 mins, the furnace was heated to 450° C. for 1.5 h under a gas flow of H₂ (10 s.c.c.m, standard cubic centimeter per minute) and Ar (90 s.c.c.m). After cooling to room temperature, the product was taken out and mixed with sulfur powder (600 mg), afterwards the obtained uniform mixture was loaded into an alumina crucible and then placed in the center of the furnace. Next, the quartz tube was vacuumed and refilled with Ar for three times to remove the air inside the tube. After purging the tube with Ar (500 s.c.c.m) for 10 mins, the furnace was heated to 450° C. for 1.5 h under a gas flow of H₂ (10 s.c.c.m) and Ar (90 s.c.c.m). After the reaction was completed, the obtained precursor was taken out when the furnace was naturally cooled to room temperature. Subsequently, 10 mg of the prepared precursor was loaded in a quartz crucible, and one piece of fresh-cleaved fluorophlogopite mica substrate was covered on the top of the precursor. Then the crucible was placed in the center of the furnace. After the quartz tube was vacuumed and refilled with Ar three times, the furnace was heated to 780° C. under a gas flow of Ar (80 s.c.c.m). After that, the tube was purged with H₂/Ar mixed gas (20% H₂/80% Ar) with a flow rate of 100 s.c.c.m. for 5 mins. After the reaction, the furnace power was turned off and the furnace was quickly moved out of the heating zone. Finally, the as-grown 2H/1T′ MoS₂ heterophase junctions on the mica substrate were prepared.

### Characterization of 2H/1T′ MoS₂ Heterophase Junctions

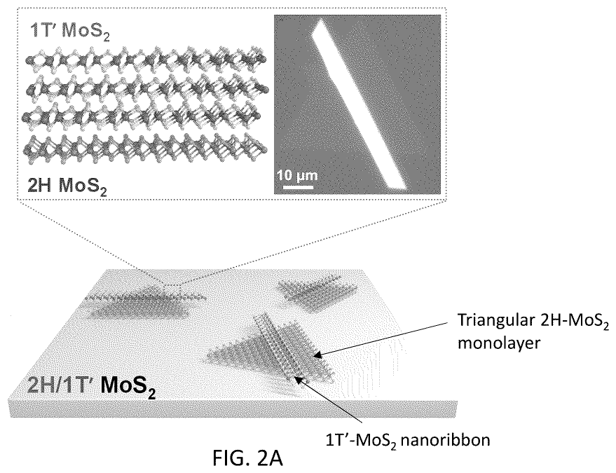

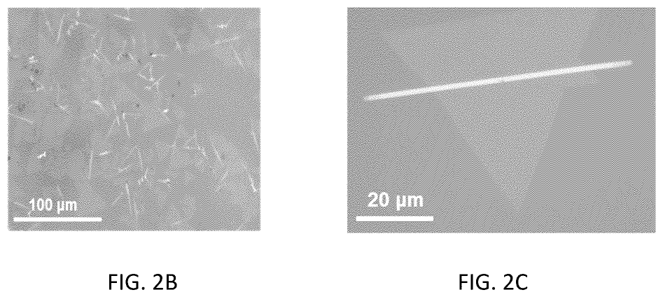

FIG. 2A shows a schematic diagram and a typical optical image (insert of FIG. 2A) of the prepared 2H/1T′ MoS₂ heterophase junctions, where the top 1T′ MoS₂ and the bottom 2H MoS₂ can be clearly distinguished from their optical contrast. FIGS. 2B and 2C show other optical images of the synthesized 2H/1T′ MoS₂ heterophase junctions in different scales. The heterophase junctions consisting of triangular 2H MoS₂ monolayers and 1T′ MoS₂ nanoribbons.

The 1T′ MoS₂ nanoribbon can be synthesized beyond the size of 2H MoS₂, which can allow us to fabricate the device directly based on the grown heterophase junctions and thereby avoid redundant processing steps that may damage the material. Moreover, the one-pot synthesis strategy only utilizes a single solid source and hence avoids the interface contamination compared to the traditional two-step route.

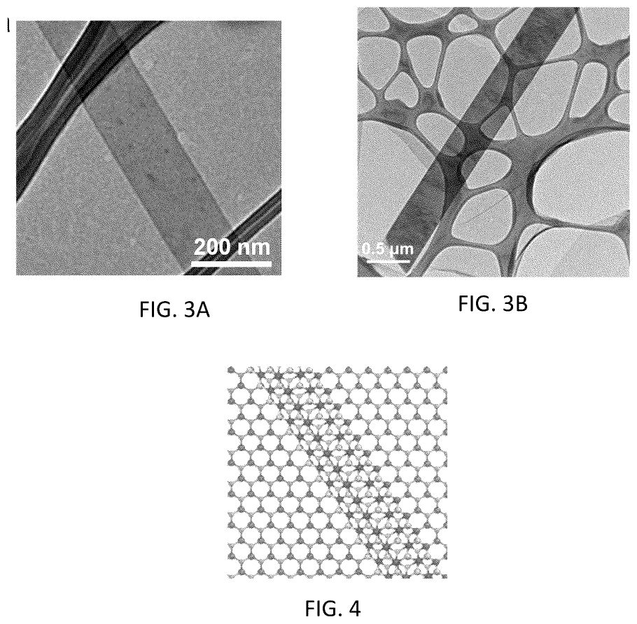

FIGS. 3A and 3B show transmission electron microscope (TEM) images of the prepared 2H/1T′ MoS₂ heterophase junctions. The morphology of 2H/1T′ MoS₂ heterophase junctions are consistent with the schematic diagram as shown in FIG. 4.

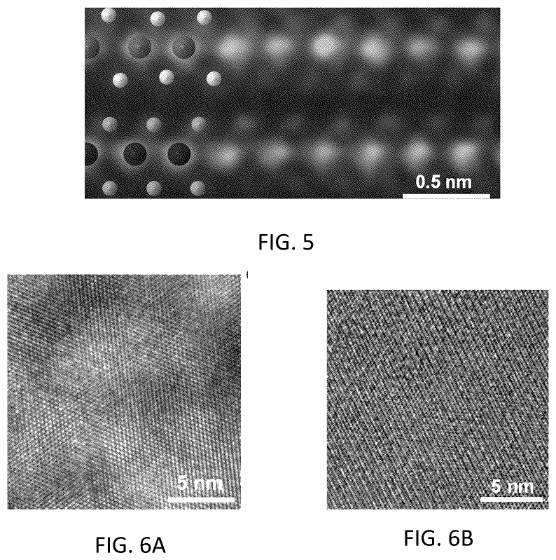

As shown in FIG. 5, the aberration-corrected high-angle annular dark-field (HAADF) scanning transmission electron microscopy (STEM) cross-section image of the prepared 2H/1T′ MoS₂ heterophase junctions exhibits clear atomic boundaries along the heterophase interface without any obvious atomic mixing or defects.

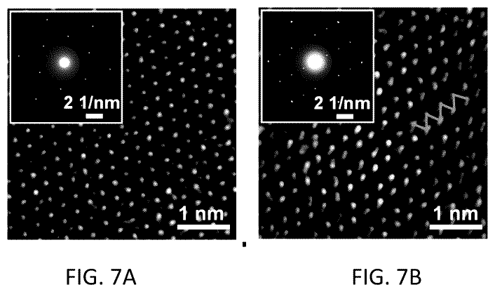

Referring to FIGS. 6A and 6B, high-resolution (HR) TEM images of 2H MoS₂ (FIG. 6A) and 1T′ MoS₂ (FIG. 6B) clearly show the obviously different atomic structures between distorted octahedral 1T′ and trigonal prismatic 2H phases. This feature is more apparent in the atomically resolved HAADF-STEM images of the 2H MoS₂ in FIG. 7A and 1T′ MoS₂ in FIG. 7B. The 1T′ MoS₂ presents clear zigzag chains which is consistent with previous literatures. Moreover, in comparison with the hexagonal symmetry spots shown in the selected area electron diffraction (SAED) pattern of 2H MoS₂ (Inset of FIG. 7A), 1T′ MoS₂ exhibits periodic spots with a rectangular symmetry (Inset of FIG. 7B).

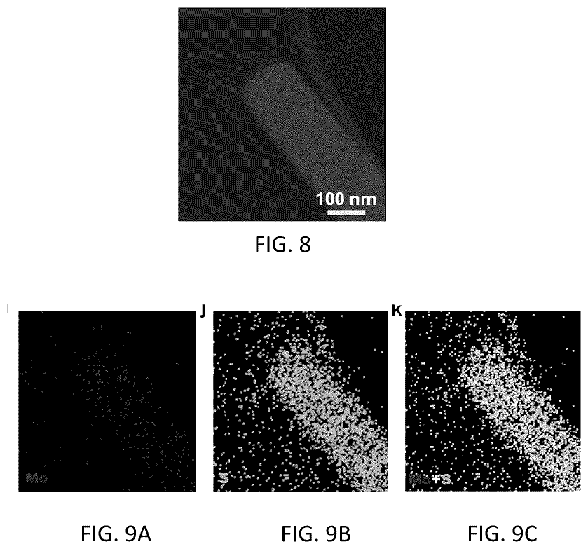

FIG. 8 shows a dark-field HRTEM image of the 2H/1T′ MoS₂ heterophase junctions. FIGS. 9A to 9C show elemental mapping images of Mo L signals, S K signals and overlap of Mo L and S K signals for the 2H/1T′ MoS₂ heterophase junctions, respectively. As shown, the signals of Mo and S are uniformly distributed in the 2H/1T′ MoS₂ heterophase junctions. These results confirm that the 2H/1T′ MoS₂ heterophase junctions have high purity, good crystallinity and well-defined heterophase boundary.

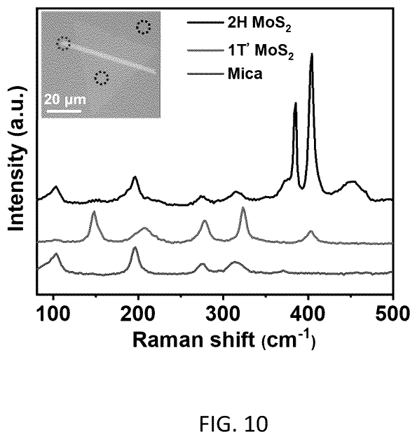

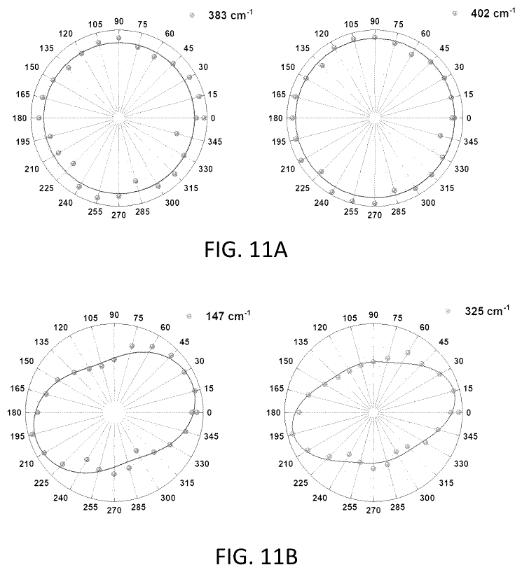

FIG. 10 shows Raman spectra of 2H MoS₂, 1T′ MoS₂ , and mica substrate. A typical optical image of the 2H/1T′ MoS₂ heterophase junctions is shown in the inset of FIG. 10. As shown, different from the two typical Raman peaks (385 and 404 cm¹) of 2H MoS₂, five different Raman peaks (148 cm⁻¹, 206 cm⁻¹, 277 cm⁻¹, 323 cm⁻¹ and 403 cm⁻¹) are observed from the 1T′ MoS₂ region. The angle-dependent Raman intensities of 2H MoS₂ (FIG. 11A) and 1T′ MoS₂ (FIG. 11B) also exhibit clear differences, since 2H MoS₂ monolayer displays no angle dependence.

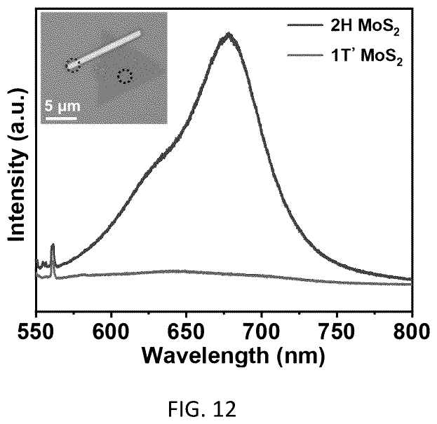

The photoluminescence (PL) spectra of 1T′ MoS₂ and 2H MoS₂ are shown in FIG. 12. 1T′ MoS₂ shows a metallic property without absorption peaks while 2H MoS₂ presents a semiconducting feature with a strong sharp exciton peak at 677 nm, which is a typical PL characteristic spectrum of monolayer MoS₂ .

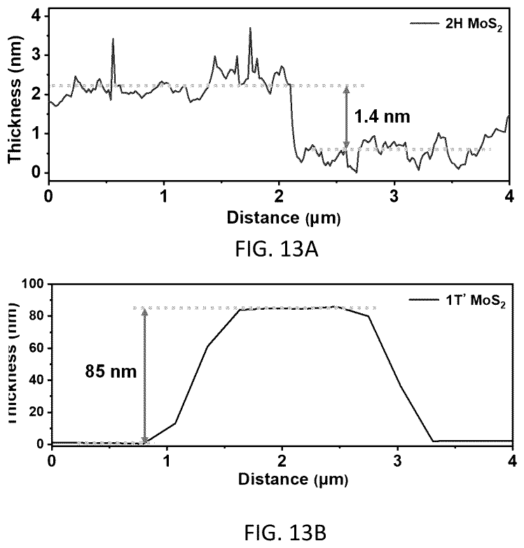

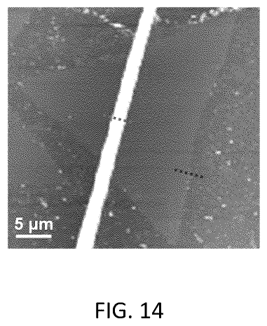

FIGS. 13A and 13B show thickness measurement results of 1T′ MoS₂ and 2H MoS₂ regions respectively. Combined with the atomic force microscope (AFM) image (FIG. 14) and the distance between the two typical Raman peaks of 2H MoS₂, it can be further proved that the CVD-grown 2H MoS₂ is monolayer.

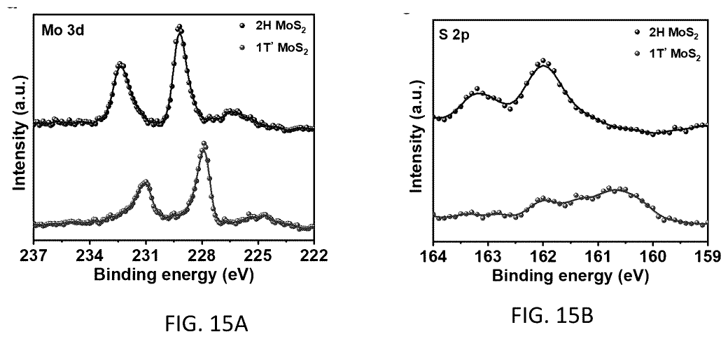

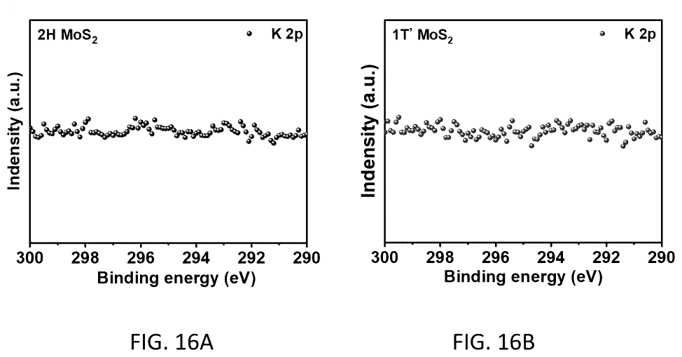

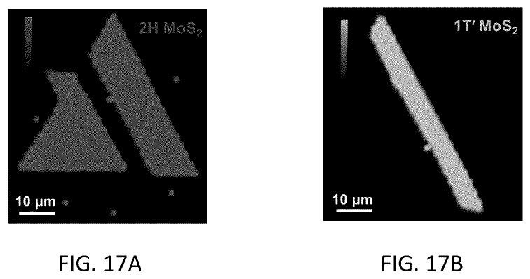

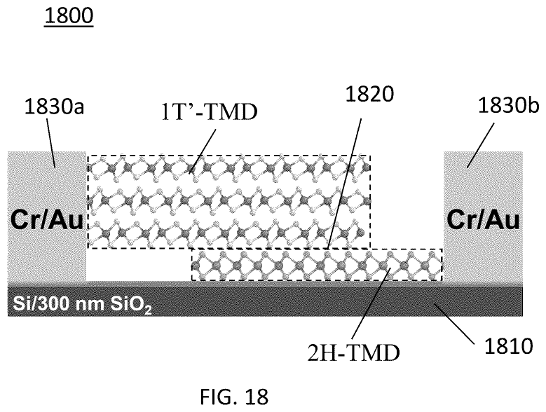

FIGS. 15A and 15B show micro-zone X-ray photoelectron spectroscopy (XPS) spectra of the Mo 3d and S 2p orbits of the 2H MoS₂ and 1T′ MoS₂ regions among the 2H/1T′ MoS₂ heterophase junctions respectively. FIGS. 16A and 16B show XPS spectra of the K 2p orbits of the 2H MoS₂ and 1T′ MoS₂ regions respectively. The Mo 3d peaks of 1T′-MoS₂ located at 227.9 and 231 eV correspond to 3d_{5/2} and 3d_{3/2} orbits, respectively, whereas the Mo 3d peaks of 2H MoS₂ shift to higher binding energies (229.2 and 232.4 eV). A similar offset is also observed in the binding energy of the S 2p orbits. Besides, no K 2p signal is detected, indicating the complete removal of K in the synthesized heterophase junctions. The uniform signals in the Raman mapping images of the 2H MoS₂ (FIG. 17A) and the 1T′ MoS₂ (FIG. 17B) demonstrate the high crystalline quality and phase purity of the as-prepared junctions.

### Fabrication of 2H/1T′ MoS₂ Heterophase Junction-Based Device

As large-scale 1T′ MoS₂ nanoribbon can be grown beyond the region of 2H MoS₂, directly

fabricating devices is allowed by using the as-prepared heterophase junctions without additional post-processing steps.

In one embodiment, to fabricate a 2H/1T′ MoS₂ heterophase junction-based device, a 2H/1T′ MoS₂ heterophase junction as grown by the synthetic method provided by the present invention was transferred onto a Si/SiO₂ substrate. Firstly, the fluorophlogopite mica substrate grown with 2H/1T′ MoS₂ heterophase junctions was coated with poly (methyl methacrylate) (PMMA 495, A8, Microchem) at 4000 r.p.m for 40 s, followed by baking at 80° C. for 30 mins on a hotplate. Then the mica was soaked in deionized water. After the PMMA film dropped out from the mica substrate, the film was scooped up by a freshly cleaned 300-nm-thick SiO₂/ Si substrate and baked at 80° C. for 10 mins on a hotplate to promote the adhesion of 2H/1T′ MoS₂ heterophase junctions on the SiO₂/Si substrate. The PMMA was removed by soaking the substrate in acetone for 20 min and the 2H/1T′ MoS₂ heterophase junctions were left on the SiO₂/Si substrate. Finally, Cr (8 nm)/Au (32 nm) electrodes were fabricated on the as-synthesized monolayer crystals by employing typical lithography procedures.

### Characterization of 2H/1T′ MoS₂ Heterophase Junction-Based Device

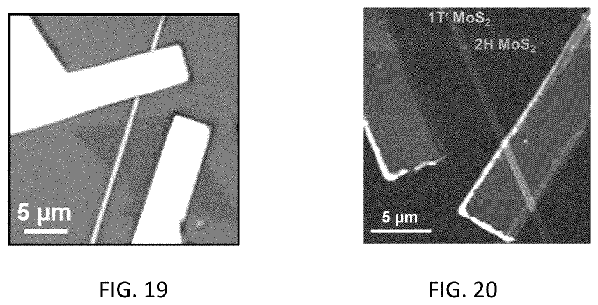

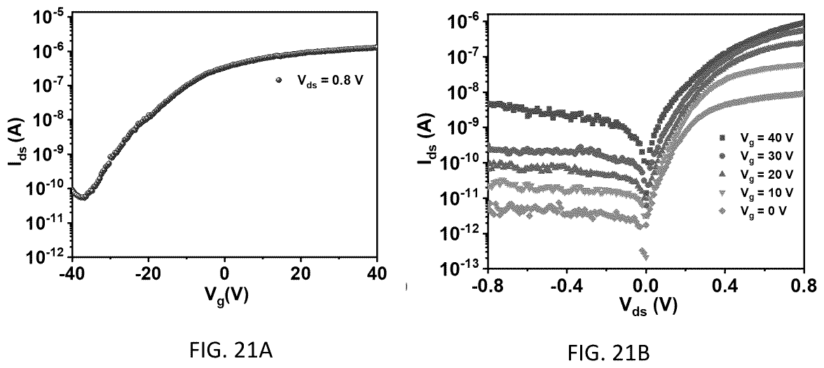

FIG. 19 shows a typical optical image of the 2H/1T′ MoS₂ heterophase junction-based device. The corresponding AFM image in FIG. 20 reveals that the device has a clean surface. The transfer curve of the device in FIG. 21A presents a typical semiconducting n-type behavior with an on-off ratio of about 10⁵. The output characteristics (I_{ds}-V_{ds}) under different gate voltages in FIG. 21B reveal that the I_{ds} increases gradually with the V_{g} varying from 0 to 40 V.

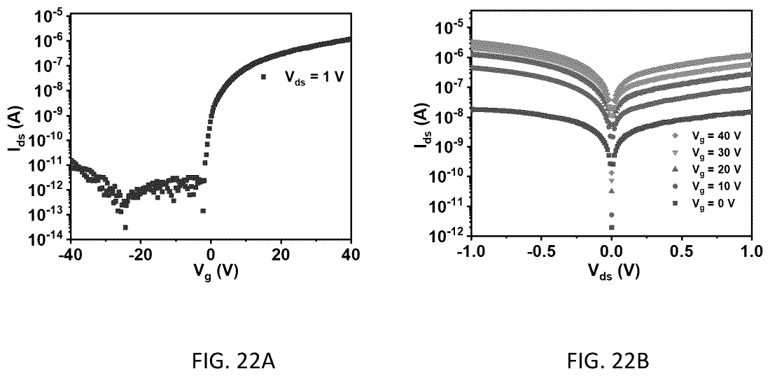

It is worth noting that the transfer curve and gate-tunable output curves of the 2H/1T′ MoS₂ heterophase junction-based device also exhibit prominent current rectification behavior in comparison with those of pure 2H MoS₂ (FIGS. 22A and 22B), further confirming the formation of Schottky junction across the interface of 1T′ and 2H MoS₂.

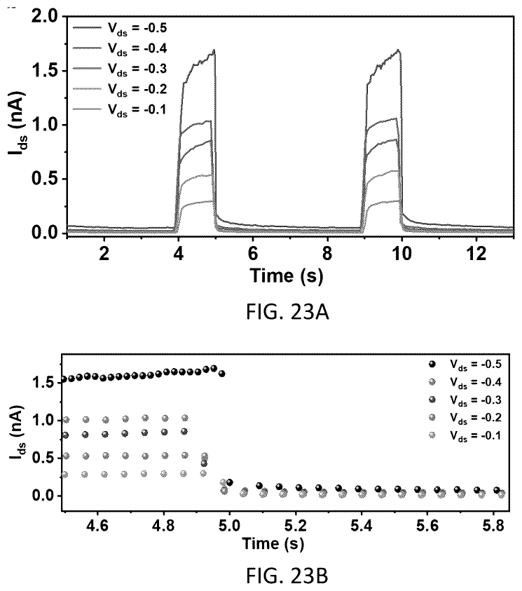

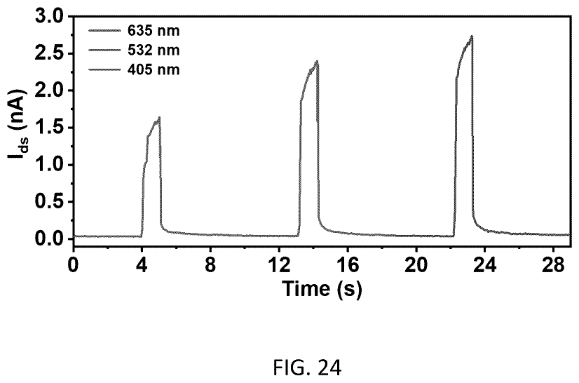

In addition, benefiting from the Schottky junction, the device shows a good optoelectronic performance. Under negative drain-source bias and gate voltage, an ultralow dark current at an order of 10⁻¹¹ A is achieved. FIG. 23A shows the time-resolved photocurrents of the device at different V_{ds} biases under a 532 nm laser with 3.52 mW/cm² input power. The photocurrent increases gradually with the increase of the drain-source voltage, and a high responsivity of 1.07 A/W is realized under −0.5 V drain-source bias. It can also be seen from FIG. 23A that the photocurrent rises rapidly under laser irradiation, and then decays sharply when the laser is turned off in all curves. The falling time is less than 24 ms (see FIG. 23B) which is limited by the resolution of our measurement equipments. In addition, referring to the photo-switching characteristics as shown in FIG. 24, for different wavelengths, the device also shows high responsivity and fast response time. These inspiring results highlight the promising potential of 2H/1T′ MoS₂ heterophase junction phototransistors in practical applications

The embodiments may be chosen and described in order to best explain the principles of the invention and its practical application, thereby enabling others skilled in the art to understand the invention for various embodiments and with various modifications that are suited to the particular use contemplated. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations. While the apparatuses disclosed herein have been described with reference to particular structures, shapes, materials, composition of matter and relationships . . . etc., these descriptions and illustrations are not limiting. Modifications may be made to adapt a particular situation to the objective, spirit and scope of the present disclosure. All such modifications are intended to be within the scope of the claims appended hereto.

1. A method for synthesizing 2H/1T′ transition metal dichalcogenide (TMD) heterophase junctions, comprising:
mixing a transition metal compound powder and a first chalcogen powder to form a first mixture;
heating up the first mixture to a first heating temperature in a chemical vapour deposition (CVD) furnace filled with Ar gas;
keeping the first mixture at the first heating temperature for a first heating time under a first mixed gas flow of H₂ and Ar to form a first precursor;
mixing the first precursor with a second chalcogen powder to form a second mixture;
heating up the second mixture to a second heating temperature in a CVD furnace filled with Ar gas;
keeping the second mixture at the second heating temperature for a second heating time under a second mixed gas flow of H₂ and Ar to form a second precursor;
placing a substrate on top of the second precursor;
heating up the second precursor and the substrate to a growth temperature in a CVD furnace filled with Ar gas;
keeping the second precursor and the substrate at the growth temperature for a first growth time under a gas flow of Ar to grow a 2H TMD layer on the substrate;
keeping the second precursor and the substrate at the growth temperature for a second growth time under a third mixed gas flow of H₂ and Ar to grow a 1T′ TMD layer above the grown 2H TMD layer on the substrate; and
cooling down rapidly the substrate grown with the 2H/1T′ TMD heterophase junctions.

2. The method of claim 1, further comprising grinding the first mixture in an agate mortar, transferring the first mixture into a first alumina crucible and placing the first alumina crucible at a center position in the CVD furnace before heating up the first mixture in the CVD furnace.

3. The method of claim 1, further comprising transferring the second mixture into a second alumina crucible and placing the second alumina crucible at a center position in the CVD furnace before heating up the second mixture in the CVD furnace.

4. The method of claim 1, further comprising transferring the second precursor into a quartz crucible before the substrate being placed on top of the second precursor and placing the quartz crucible at a center position in the CVD furnace before heating up the third mixture in the CVD furnace.

5. The method of claim 1, wherein the substrate is a fluorophlogopite mica substrate or a sapphire substrate.

6. The method of claim 1, wherein
a flow rate ratio for H₂ to Ar in the first mixed gas flow is equal to 1:9; and
the first temperature ranges from 400 to 500° C. and the first heating time ranges from 1 to 2 hours.

7. The method of claim 1, wherein
a flow rate ratio for H₂ to Ar in the second mixed gas flow is equal to 1:9; and
the second temperature ranges from 400 to 500° C. and the second heating time ranges from 1 to 2 hours.

8. The method of claim 1, wherein
a flow rate ratio for H₂ to Ar in the third mixed gas flow is equal to 2:8; and
the third temperature ranges from 750 to 800° C. and the third heating time ranges from 4 to 6 minutes.

9. The method of claim 1, wherein the transition metal compound powder is a molybdenum compound powder and both the first and second chalcogen powders are sulfur powders such that the 2H/1T′ TMD heterophase junctions grown on the substrate are 2H/1T′ molybdenum disulfide heterophase junctions.

10. The method of claim 9, wherein the molybdenum compound powder is a potassium molybdate (K₂MoO₄) powder.

11. A 2H/1T′ transition metal dichalcogenide (TMD) heterophase junction-based device, comprising:
a substrate;
a 2H/1T′ TMD heterophase junction deposited on the substrate and including a 1T′-TMD region and a 2H-TMD region; and
a pair of electrodes connected to the 1T′-TMD and the 2H-TMD regions respectively.

12. The 2H/1T′ TMD heterophase junction-based device of claim 11, wherein the 1T′-TMD region is formed of 1T′-MoS₂ crystal and the 2H-TMD region is formed of 2H-MoS₂ crystal.

13. The 2H/1T′ MoS₂ heterophase junction-based device of claim 11, wherein the substrate is a SiO₂/Si substrate.

14. The 2H/1T′ MoS₂ heterophase junction-based device of claim 11, wherein the electrodes are made of Cr/Au layer.
